(19) United States
(12) Patent Application Publication
(10) Pub. No.: US 2026/0313823 A1
(43) Pub. Date: Oct. 8, 2026

(54) SERVICING SYSTEM FOR SERVER CASSETTES

(71) Applicant: AirSys Holding, Inc., Greer, SC (US)

(72) Inventors: Mengyuan Yuan, Anderson, SC (US); Nan Chen, Alpharetta, GA (US); Yunshui Chen, Greer, SC (US)

(21) Appl. No.: 19/398,515

(22) Filed: Nov. 24, 2025

Related U.S. Application Data
(60) Provisional application No. 63/782,795, filed on Apr. 3, 2025.

(51) Int. Cl. H05K 7/14; H05K 7/18; H05K 7/20

(52) U.S. Cl. CPC H05K 7/1489; H05K 7/1494; H05K 7/183; H05K 7/2039; H05K 7/20772

(57) ABSTRACT

A server rack servicing system may include a rack and a movable trolley. The rack includes a plurality of horizontal shelves, each shelf configured to store a plurality of vertically-disposed server cassettes. The trolley includes an elevator, a platform, coupled to the elevator, configured to hold server cassettes removed from the rack or to be installed to the rack, and an actuator, coupled to the elevator, configured to cause the elevator to move the platform to vertical shelf positions of the rack.

### PRIORITY

This patent application claims priority from Provisional United States Patent Application number 63/782,795, filed Apr. 3, 2025, entitled DISTRIBUTED SERVER RACK COOLING SYSTEM and naming Nan Chen, Mengyuan Yuan, Zhipeng Zhao, and Yunshui Chen as the inventors, the disclosure of which is incorporated herein in its entirety, by reference.

### FIELD

Illustrative embodiments of the invention generally relate to data center server cooling and servicing and, more particularly, various embodiments of the invention relate to a servicing system for server cassettes in server racks of data centers.

### BACKGROUND

Data centers may include large numbers of computers, data storage, and networking resources. The computers are typically servers, each including one or more very powerful processors and significant memory resources. The servers consume significant amounts of power and produce a large amount of heat, which must be dealt with by the data center.

Data center cooling maintains the right temperatures for servers and associated equipment to prevent overheating and server shutdown and ensure reliable and efficient performance. Formerly, data centers used various forms of air cooling and refrigeration to maintain proper equipment temperatures. However, with dramatic increases in processor and computer operating speeds, traditional air cooling is insufficient. Newer systems use various forms of liquid or oil cooling to maintain equipment temperatures.

### SUMMARY OF VARIOUS EMBODIMENTS

In accordance with one embodiment of the invention, a server rack servicing system may include a rack and a movable trolley. The rack includes a plurality of horizontal shelves, each shelf configured to store a plurality of vertically-disposed server cassettes.

The trolley includes an elevator, a platform, coupled to the elevator, configured to hold server cassettes removed from the rack or to be installed to the rack, and an actuator, coupled to the elevator, configured to cause the elevator to move the platform to vertical shelf positions of the rack.

In accordance with other embodiments, the server rack servicing system may include left and right fences, coupled to the platform and extending upward, configured to retain a server cassette on the platform and prevent the server cassette from falling sideways off the platform.

In accordance with other embodiments, the server rack servicing system may include a plurality of pans, each below one of the plurality of shelves, configured to catch dielectric coolant leaks from the plurality of server cassettes, wherein each of the plurality of pans may be slidingly removed from the rack and emptied.

In accordance with other embodiments, the server cassettes each include a server, a primary loop cooling system, and a heat exchanger, where the primary loop cooling system circulates a dielectric coolant through a sprayer to cool the server and transfers heat to a secondary loop cooling system through the heat exchanger.

In accordance with other embodiments, the server rack servicing system may include a plurality of rack rails, disposed below each of the plurality of server cassettes, configured to allow the server cassettes to slide in a forward or backward direction while preventing lateral movement of the server cassettes. Each of the plurality of server cassettes may include a rail interface affixed to a bottom of the server cassette and configured to retain the server cassette to a rack rail.

In accordance with other embodiments, each rack rail may include a plurality of vertical holes configured to secure a server cassette at different positions along the rack rail by a fastener.

In accordance with other embodiments, the platform may include a trolley rail affixed to a top surface of the platform. The trolley rail is configured to allow the rail interface of server cassettes to slide in forward and backward directions along the trolley rail.

In accordance with other embodiments, the server rack servicing system may include a rail alignment spacer, extending from a distal end of the platform, configured to engage an end of a rack rail to axially align the rack rail with the trolley rail when the trolley is moved forward to a server cassette position and the trolley rail is at a same height as a rack rail corresponding to the server cassette position .

In accordance with other embodiments, the server rack servicing system may include wheel locks, coupled to a plurality of wheels of the trolley, configured to prevent trolley movement when the rail alignment spacer is coupled to the rack rail and the wheel locks are engaged.

In accordance with other embodiments, a server cassette may be pulled forwardly onto the platform in response to the fastener does not secure the server cassette to the rack rail and water and electrical connections at the rear of the server cassette have been disconnected.

In accordance with other embodiments, a server cassette may be pushed rearwardly from the platform onto the rack rail and secured to the rack rail with the fastener.

In accordance with another embodiment, a method of removing a server cassette from a rack may include positioning a trolley in front of a server cassette to be removed from a rack, the rack including a plurality of horizontal shelves and each shelf is configured to store a plurality of vertically-disposed server cassettes, the trolley including an elevator, a platform, coupled to the elevator, and an actuator, coupled to the elevator, moving the platform to a shelf height of the rack corresponding to the server cassette to be removed, engaging a rack rail of the server cassette to be removed with a rack alignment spacer coupled to a distal end of the platform such that the rack rail is axially aligned with a trolley rail coupled to the platform, pulling the server cassette forward onto the trolley rail, moving the trolley in a backward direction from the rack to disengage the rack alignment spacer from the rack rail, and lowering the platform, by the actuator, to a vertical height on the trolley deemed as safe for transporting the server cassette on the trolley. The platform is configured to hold server cassettes removed from the rack or to be installed to the rack.

The actuator is configured to cause the elevator to move the platform to vertical shelf positions of the rack.

In accordance with other embodiments, before pulling the server cassette forward, the method may include uncoupling the server cassette to be removed from the rack rail, by removing a fastener and disconnecting cooling and electrical connections to the server cassette.

In accordance with other embodiments, before disconnecting cooling and electrical connections to the server cassette, the method may include inactivating a server in the server cassette.

In accordance with other embodiments, before engaging the rack rail of the server cassette to be removed with the rack alignment spacer, the method may include adjusting, by an elevator speed control of the trolley, a height of the platform until the rack rail is axially aligned with the trolley rail.

In accordance with other embodiments, before pulling the server cassette forward onto the trolley rail, the method may include locking, by wheel locks affixed to a plurality of trolley wheels, the plurality of trolley wheels to prevent trolley movement.

In accordance with other embodiments, a method of installing a server cassette to a rack may include positioning a trolley in front of an empty server cassette position in a rack, the rack including a plurality of horizontal shelves, each shelf configured to store a plurality of vertically-disposed server cassettes, the trolley including an elevator, a platform, coupled to the elevator, and an actuator, coupled to the elevator, moving the platform to a shelf height of the rack corresponding to the empty server cassette position, engaging a rack rail corresponding to the empty server cassette position with a rack alignment spacer coupled to a distal end of the platform such that the rack rail is axially aligned with a trolley rail coupled to the platform and supporting the server cassette to be installed, pushing the server cassette backward into the empty server cassette position along the rack rail, and moving the trolley in a backward direction from the rack to disengage the rack alignment spacer from the rack rail. The platform supports a server cassette to be

installed to the rack. The actuator is configured to cause the elevator to move the platform to vertical shelf positions of the rack.

In accordance with other embodiments, before engaging the rack rail of the server cassette to be installed with the rack alignment spacer, the method may include adjusting, by an elevator speed control of the trolley, a height of the platform until the rack rail is axially aligned with the trolley rail.

In accordance with other embodiments, before pushing the server cassette backward onto the rack rail, the method may include locking, by wheel locks affixed to a plurality of trolley wheels, the plurality of trolley wheels to prevent trolley movement. After pushing the server cassette backward onto the rack rail, the method may include unlocking the wheel lock.

In accordance with other embodiments, after pushing the server cassette backward onto the rack rail, the method may include securing the server cassette to the rack rail, by a fastener and connecting cooling and electrical connections to the server cassette.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a front isometric view of a server rack in a data center in accordance with illustrative embodiments of the invention.

FIG. 2 schematically shows a front isometric view of a server rack with a swung-out control panel in accordance with illustrative embodiments of the invention.

FIG. 3 schematically shows a front isometric view of a server rack with a server cassette extended in accordance with illustrative embodiments of the invention.

FIG. 4 schematically shows a detail view of a server cassette rail in accordance with illustrative embodiments of the invention.

FIG. 5 schematically shows a right rear isometric view of a server rack with covers removed in accordance with illustrative embodiments of the invention.

FIG. 6 schematically shows a left rear isometric view of a server rack with covers removed in accordance with illustrative embodiments of the invention.

FIG. 7 schematically shows a left rear isometric view of a server rack secondary cooling loop connections in accordance with illustrative embodiments of the invention.

FIG. 8 schematically shows a front isometric view of a trolley for servicing a server cassette in accordance with illustrative embodiments of the invention.

FIG. 9 schematically shows a rear isometric view of a trolley for servicing a server cassette in accordance with illustrative embodiments of the invention.

FIG. 10 schematically shows a front isometric view of a server rack with a trolley servicing a server cassette in accordance with illustrative embodiments of the invention.

FIG. 11 schematically shows a detail view of a rack interface to a trolley rail in accordance with embodiments of the invention.

FIG. 12 shows a flowchart of a server cassette removal process from a rack in a data center in accordance with illustrative embodiments of the invention.

FIG. 13 shows a flowchart of a server cassette installation process to a rack in a data center in accordance with illustrative embodiments of the invention.

### DESCRIPTION OF ILLUSTRATIVE EMBODIMENTS

In illustrative embodiments, a server rack may include a number of server cassettes. Each server cassette includes a server motherboard and various components supporting a primary cooling loop. The primary cooling loop transfers heat from server components to a secondary cooling loop and returns a recirculated cooled liquid coolant to continue cooling the server components. Each server cassette is individually removable from and insertable to the rack, which facilitates server or cooling system repairs or upgrades.

Data centers generally includes many server computers organized into groups of racks. Each rack may include any number of servers but typically include 10-30 identical server computers in a cassette or blade format that may be individually added to or removed from a rack. Each rack often includes an associated cooling system to cool very high temperature electronic components, such as central processing units (CPUs) and/or

graphical processing units (GPUs). In some cases, other components such as memory modules/devices, northbridge, or southbridge components may be individually cooled as well. Each high-temperature component may have an associated heat sink that is cooled by air, a liquid, or a combination of air and a liquid. Older servers and components produced much less heat than modern components, so air cooling was often sufficient. However, present day individual components may produce over 500 watts of heat, requiring more advanced liquid cooling systems. Illustrative embodiments address this problem with an advanced liquid cooling system for data center applications. Details of various embodiments are discussed below.

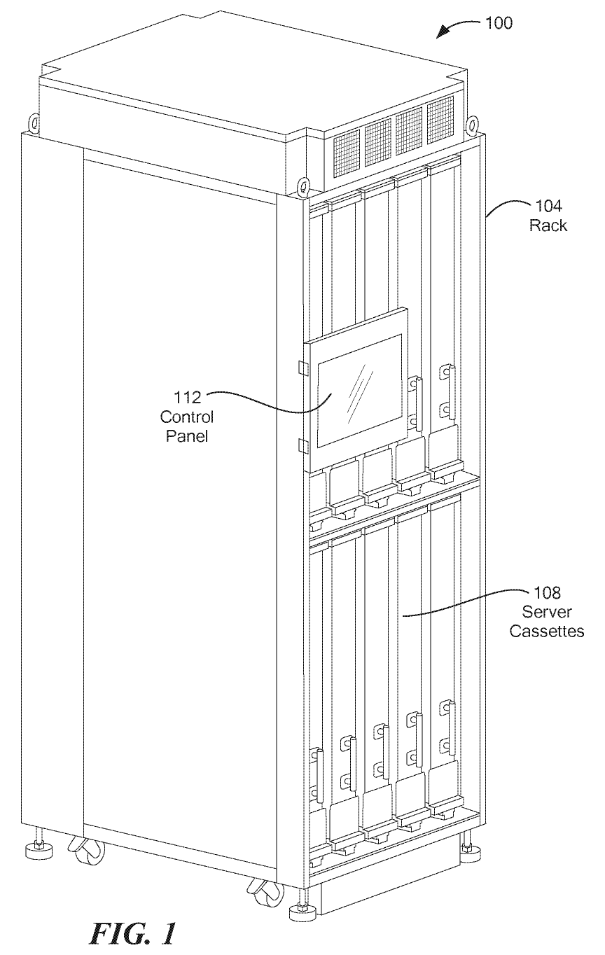

Referring to FIG. 1 a front isometric view of a server rack in a data center 100 in accordance with illustrative embodiments of the invention is shown. The rack 104 may include server cassettes 108 organized in a parallel modular fashion on one or more shelves of the rack 104. The cassettes 108 are disposed vertically to facilitate liquid cooling of a server motherboard in the server cassette 108. The server motherboard is mounted vertically sideways within the server cassette 108 to allow sprayed liquid coolant to flow to the bottom of the cassette 108 where it is temporarily stored by a coolant reservoir.

In one embodiment, the rack 104 may have a 33.5” wide form factor common with other rack equipment or may have a custom form factor. In one embodiment, the rack 104 may be moved via casters to other locations within a data center, although once in place and fully installed tends to stay in the same location. The rack 104 may include a control panel 112 to provide local management resources to the server cassettes 108, power supplies in the rack 104, or other rack 104 resources. In one embodiment, the control panel 112 may have one or more wired or wireless interfaces to allow management by external management computers. The control panel 112 may allow local maintenance personnel to take individual servers in server cassettes 108 online or offline, report temperature, pressure, or coolant flow rates from sensors within the rack 104 and server cassettes 108, and set reporting thresholds for sensors, among other items.

In addition to CPU/GPU heat sinks, other heat-producing components of server motherboards such as northbridge/southbridge controllers may require a heat sink.

Preferably, the heat sinks are oriented on the heat-producing components such that when the packaged server is oriented vertically, coolant sprayed to the heat sinks will flow off the heat sinks and flow downward by gravity. The server is packaged within an enclosure (e.g., a sheet metal enclosure) that retains the sprayed coolant within the package and provides means to remove the heated coolant from the server, cool it, and pump the cooled coolant back to a sprayer within the server cassette 108. The sprayer may include a number of spray orifices on one generally planar side that direct a controlled volume of spray to heat sinks on the server motherboard. In one embodiment, larger spray orifices are provided for heat sinks requiring a higher volume of liquid coolant and smaller spray orifices are provided for heat sinks or components requiring a lower volume of liquid coolant.

In addition to components with dedicated heat sinks, server motherboards typically include an array of memory modules for data and program storage. The memory modules are generally located in a parallel fashion on the motherboard for efficient layout and near a northbridge controller that controls the memory modules. To provide dedicated cooling for memory modules, the sprayer may include a number of dividers between adjacent memory modules. The dividers keep sprayed liquid coolant between the dividers so that it efficiently cools each memory module and limits overspray to other parts of the packaged server. The dividers may be oriented vertically such that the coolant flows between them without pooling against sprayer or motherboard surfaces.

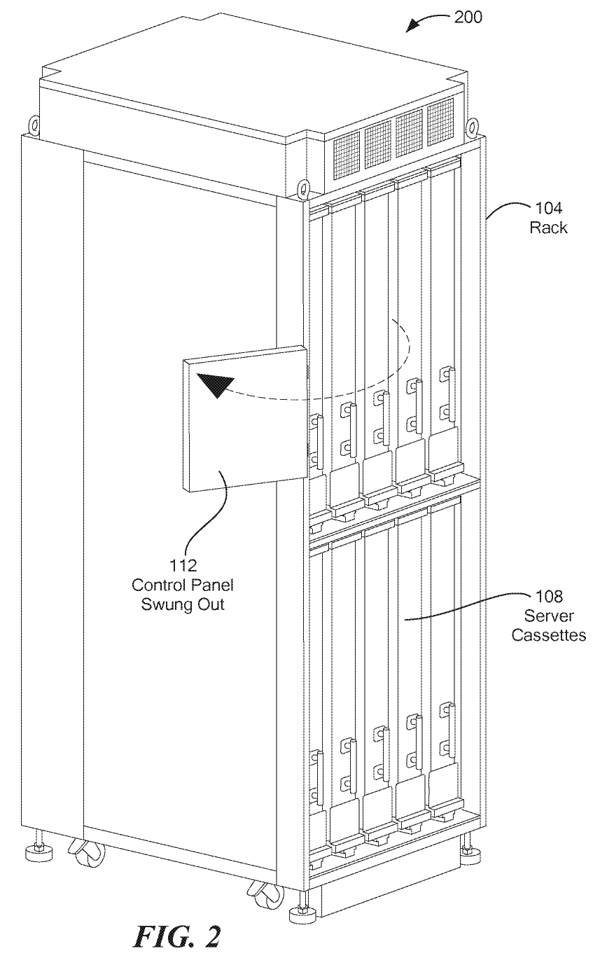

Referring to FIG. 2, a front isometric view of a server rack with a swung-out control panel 200 in accordance with illustrative embodiments of the invention is shown. The control panel 112 may include a hinged side that allows the control panel 112 to be swung out of the way to access server cassettes 108 behind the control panel 112. This eliminates the need for tools to remove assemblies and facilitates efficient servicing.

Each of the server cassettes 108 includes a primary cooling loop that recirculates a dielectric coolant (e.g., a dielectric oil) throughout a sprayer within the server cassettes 108 and accumulates in a reservoir at the bottom of the server cassettes 108. Because of the liquid coolant, and possibly also some vapor coolant, within the server cassettes 108, there is a possibility of leakage of some dielectric coolant from one or more server cassettes 108.

In some embodiments, one or more pans (not shown) may be disposed beneath the server cassettes 108 to catch any coolant leaks. In one embodiment, a single flat pan may be located on each shelf of the rack 104. In another embodiment, each server cassette 108 or number of cassettes 108 may have a coolant pan beneath it. The pans are intended to slide out and be removable and drained by maintenance personnel.

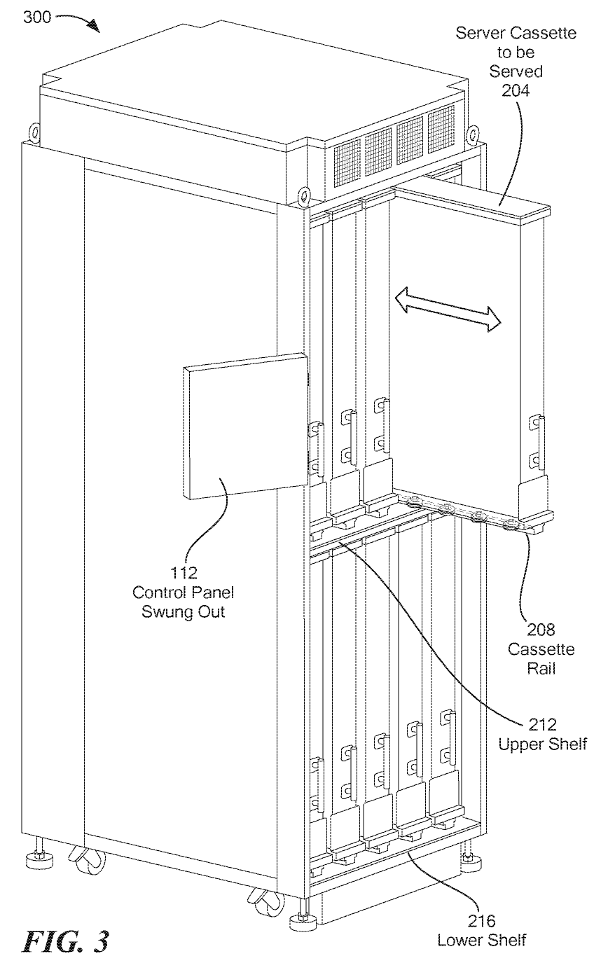

Referring to FIG. 3, a front isometric view of a server rack with a server cassette extended 300 in accordance with illustrative embodiments of the invention is shown. The rack 104 may be designed to allow server cassettes 108 to be removed from the front of the rack 104, while electrical and cooling connections are made from the rear of the rack 104. Each server cassette 108 may be mounted to a cassette rail 208 mounted to a bottom surface of each server cassette 108. This allows server cassettes 108 to slide in a forward and backward direction while the weight of the server cassette 108 is supported on the cassette rail 208.

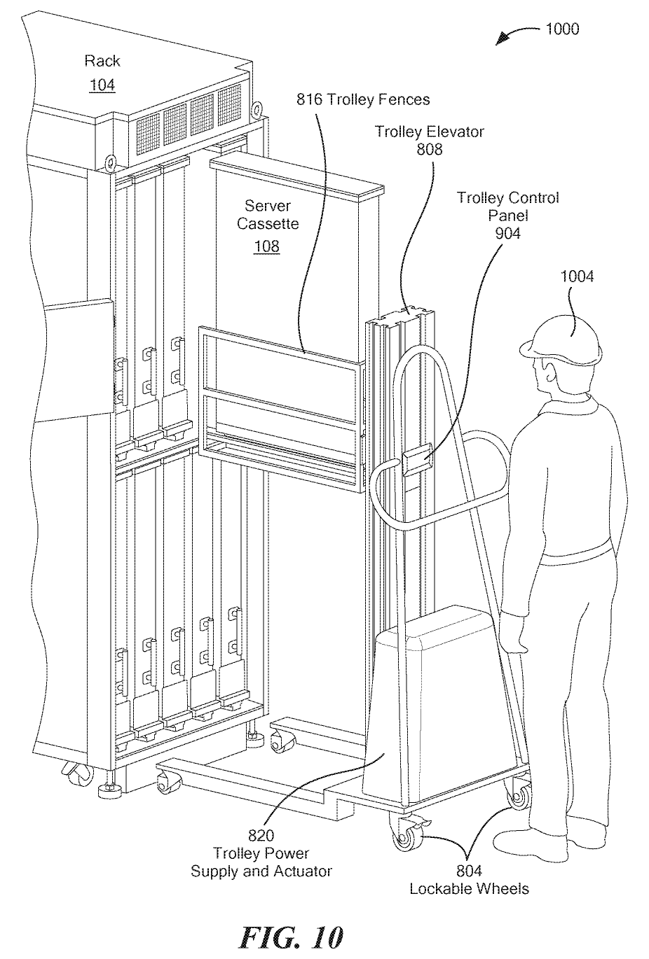

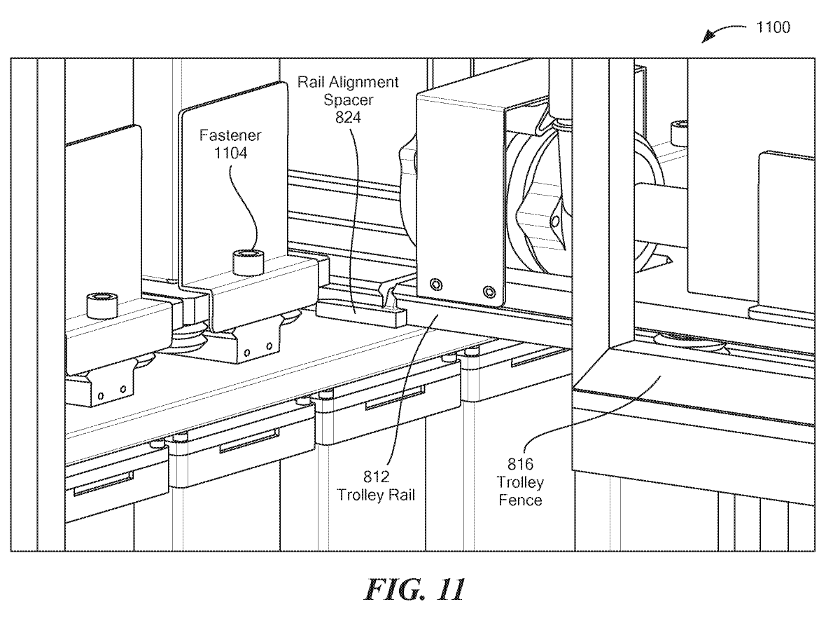

FIG. 3 illustrates a rack 104 having an upper shelf 212 and a lower shelf 216. Although two shelves 212, 216 are shown, a rack 104 may include any number of shelves. A server cassette to be serviced 204 is shown partially drawn forward from the front of the rack 104 to show how a server cassette 108 may be extended, although in practice a server cassette 108 would not be moved forward until a trolley 800 were in place and secured to the rack 104 for safety, as shown and described in FIGS. 10 and 11.

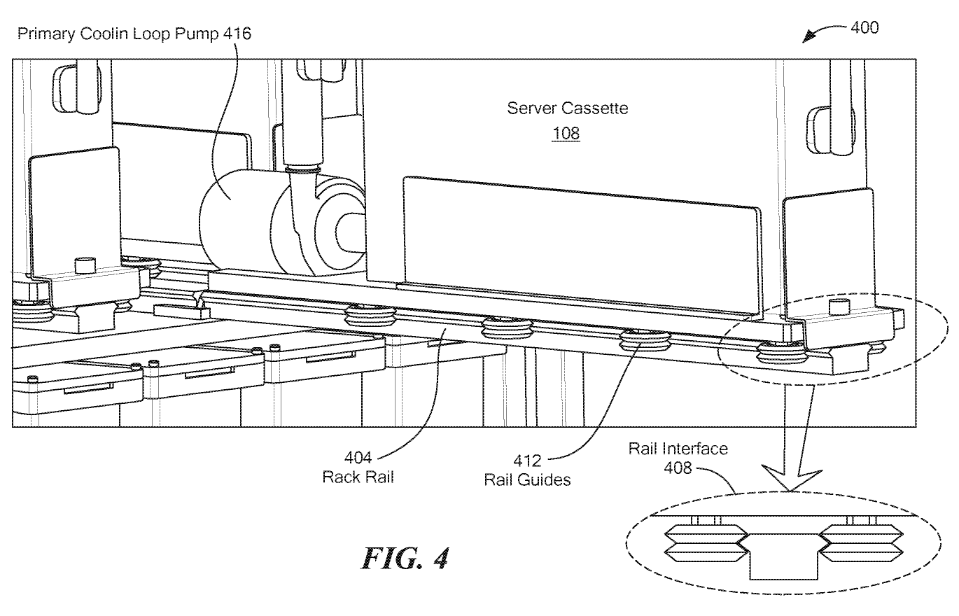

Referring to FIG. 4, a detail view 400 of a server cassette rail in accordance with illustrative embodiments of the invention is shown. FIG. 4 illustrates general features visible with an extended server cassette 108. The features include a rack rail 404, details of a rail interface 408, rail guides 412, and a primary cooling loop pump 416 affixed to the rear area of a server cassette 108. The rail guides 412 capture a lateral projection on each side of the rack rail 404 and allow the server cassette 108 to slide in a forward and backward direction. The primary cooling loop pump 416 recirculates primary cooling loop coolant through sprayers within the server cassette 108 and a heat exchanger (not shown) on the rear area of the server cassette 108 to a secondary cooling loop.

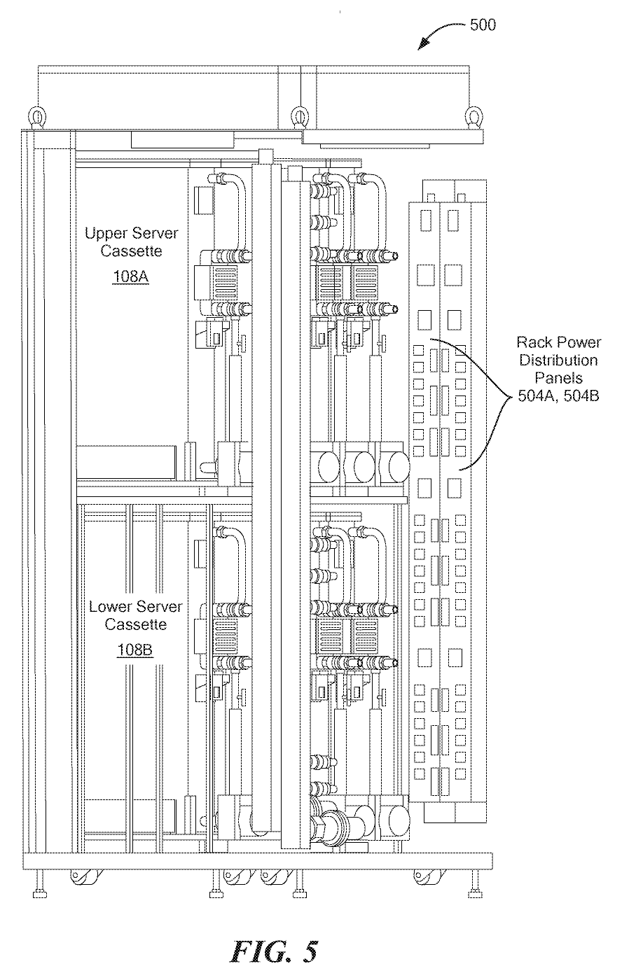

Referring to FIG. 5, a right rear isometric view of a server rack with covers removed 500 in accordance with illustrative embodiments of the invention is shown. FIG. 5 illustrates a pair of rack power distribution panels 504A, 504B that provide individual electrical power to each server cassette 108. Electrical connections (not shown) between each server cassette 108 and the rack power distribution panels 504A, 504B must be disconnected before removing a server cassette 108 from the rack 104. FIG. 5 also shows an upper server cassette 108A on an upper shelf 212 and a lower server cassette 108B on a lower shelf 216 of the rack 104.

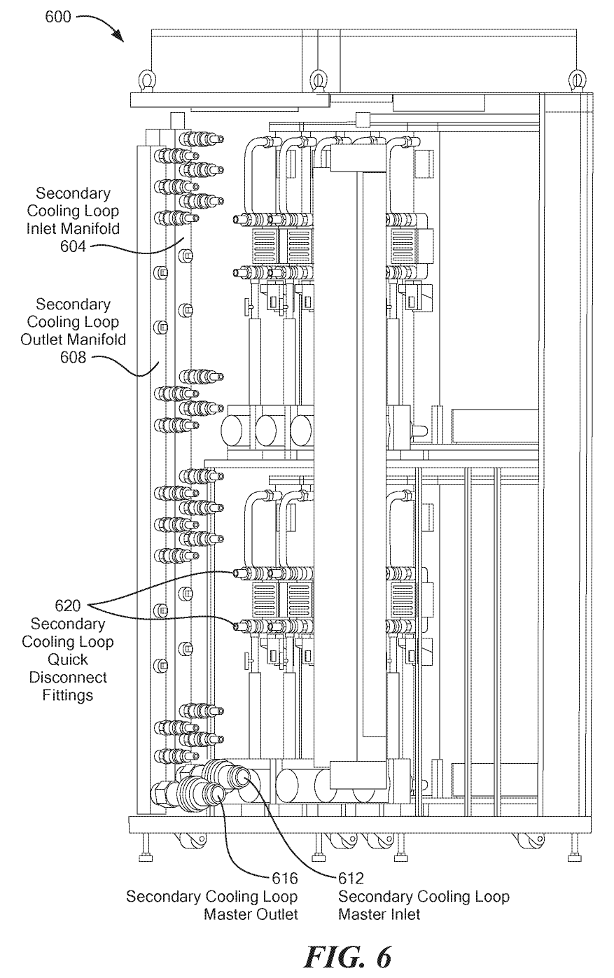

Referring to FIG. 6, a left rear isometric view 600 of a server rack with covers removed in accordance with illustrative embodiments of the invention is shown. FIG. 6 illustrates rack 104 components associated with a secondary loop cooling system for a data center. While the primary cooling loops operate completely within each server cassette 108, the secondary cooling loop includes all server racks 104 in the data center. The primary cooling loop liquid coolant is typically a dielectric fluid. The secondary cooling loop cools liquid coolant operating in the primary cooling loops through a heat exchanger affixed to the rear of each server cassette 108. Various chillers or other cooling components cool the secondary cooling loop coolant.

Shown in FIG. 6 are a secondary cooling loop inlet manifold 604 that receives liquid coolant through a secondary cooling loop master inlet 612, a secondary cooling loop outlet manifold 608 that outputs liquid coolant through a secondary cooling loop master outlet 616. Each server cassette 108 includes a pair of secondary cooling loop quick disconnect fittings 620 coupled to a heat exchanger on the rear of the server cassettes 108. The secondary cooling loop coolant is commonly water or a mixture of water and glycol.

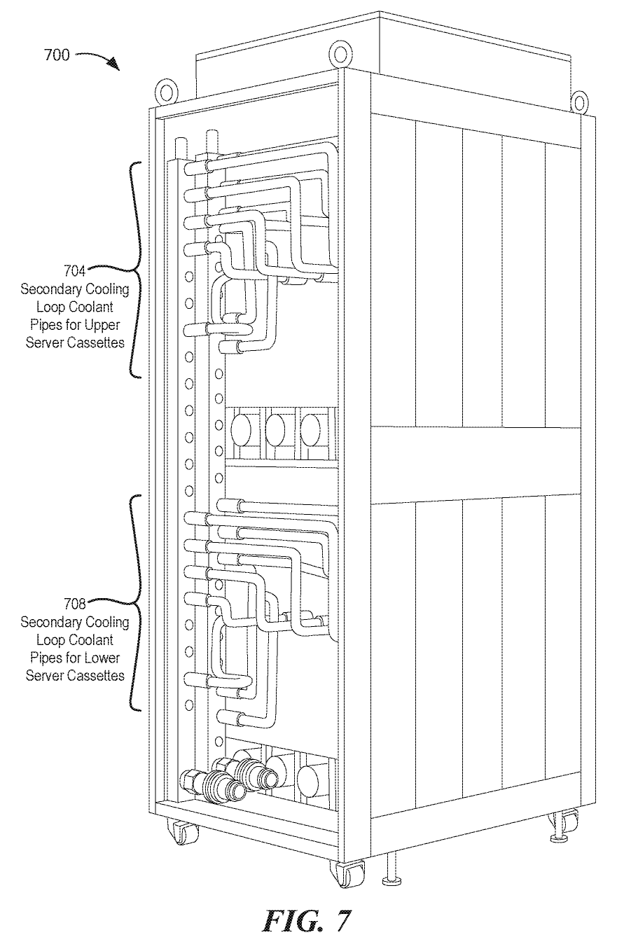

Referring to FIG. 7, a left rear isometric view 700 of server rack secondary cooling loop connections in accordance with illustrative embodiments of the invention is shown. FIG. 7 is similar to FIG. 6 but illustrates the various connecting pipes and hoses for the secondary cooling loop at the rear of a rack 104. Server cassettes 108A on the upper shelf 212 connect to the secondary cooling loop through quick disconnect fittings 620 and secondary cooling loop coolant pipes 704 for upper server cassettes 108A to the secondary

cooling loop inlet 604 and outlet 608 manifolds. Server cassettes 108B on the lower shelf 216 connect to the secondary cooling loop through quick disconnect fittings 620 and secondary cooling loop coolant pipes 708 for lower server cassettes 108B to the secondary cooling loop inlet 604 and outlet 608 manifolds.

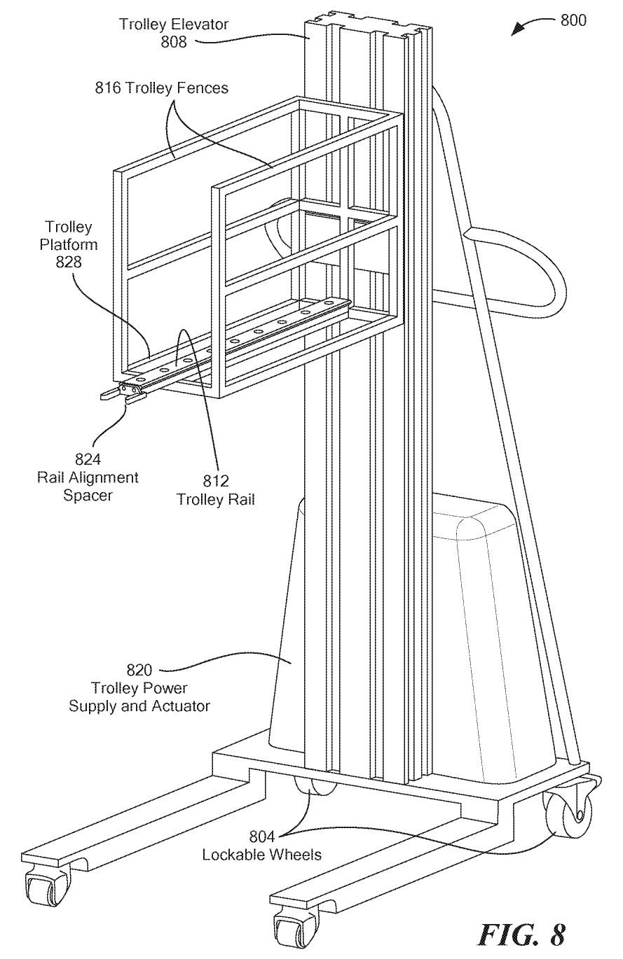

Referring to FIG. 8, a front isometric view of a trolley 800 for servicing a server cassette in accordance with illustrative embodiments of the invention is shown. The trolley 800 is a wheeled cart that safely moves server cassettes 108 between a rack 104 and a servicing facility. Server cassettes 108 may be many different sizes and can easily weigh in excess of 100 lbs. (45.4 Kg). Because of the size and weight of server cassettes 108, they may not be safely removed and carried by maintenance personnel.

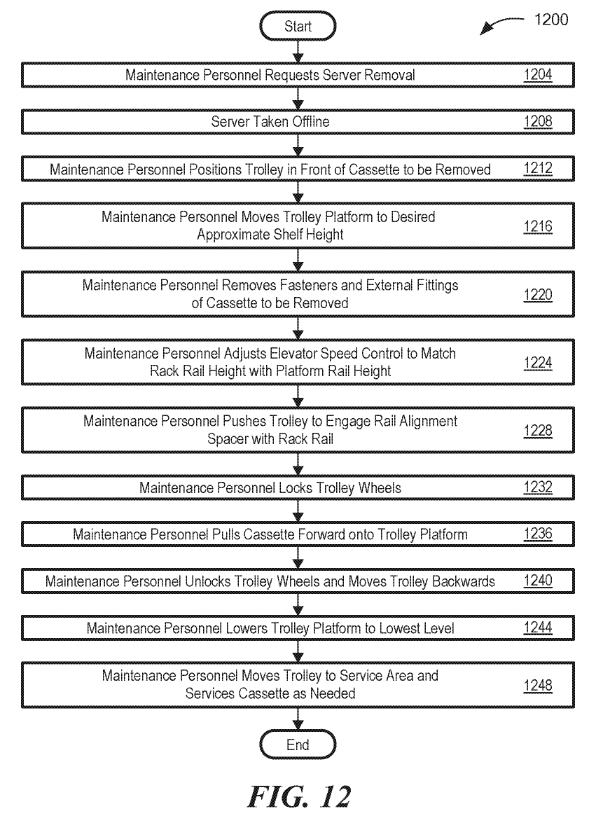

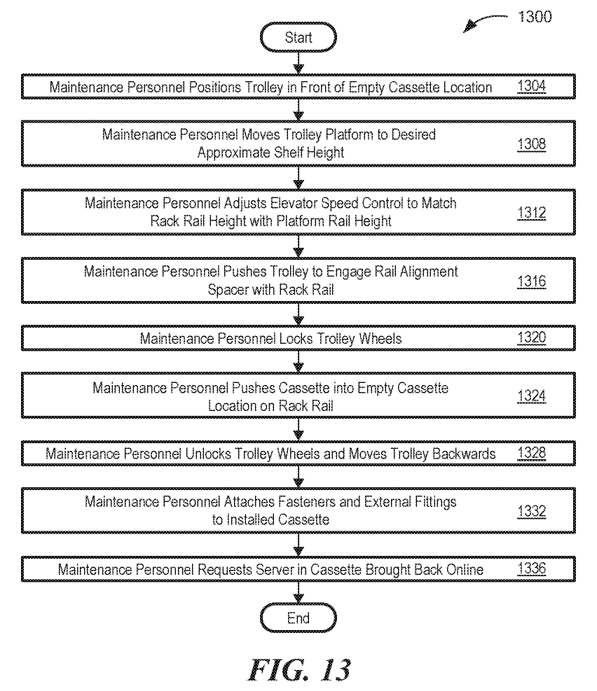

The trolley 800 includes various structural members supported by a number of wheeled casters. The wheeled casters are lockable wheels 804, which may be selectively locked and unlocked by maintenance personnel. FIGS. 12 and 13 show the points in the removal and illustration processes where the wheels are locked and unlocked. A vertical trolley elevator 808 extends upwardly from a trolley base and includes a movable member that is moved vertically by a trolley power supply and actuator 820 coupled to the trolley base. The trolley actuator may move the movable member upward or downward by a chain, drive belt, or other means within the trolley elevator 808.

The movable member is directly attached to a trolley platform 828, which may be a planar structure orthogonally attached to the movable member or a series of various tubular or square members that support a horizontal trolley rail 812. Trolley fences 816 are affixed to sides of the trolley platform 828. The trolley fences 816 keep a removed server cassette 108 on the trolley platform 828 and prevent the server cassette 108 from falling to the sides.

A rail alignment spacer 824 is affixed to a front end of the trolley rail 812 and secures the end of the trolley rail 812 to an end of the rack rail 404 for smooth transfer of the server cassette 108 from the rack rail 404 to the trolley rail 812 or from the trolley rail 812 to the rack rail 404. This is shown in more detail in FIG. 11.

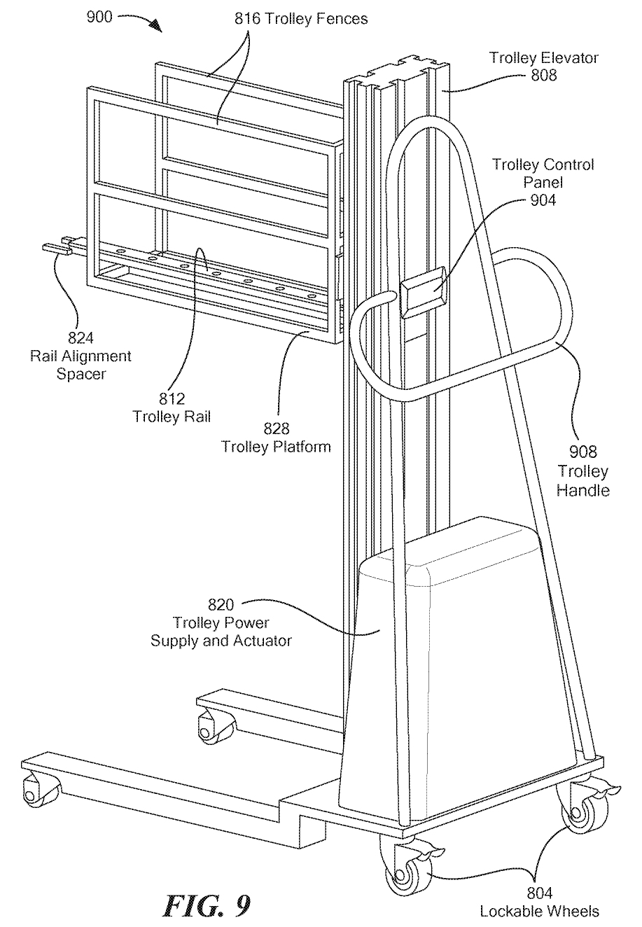

Referring to FIG. 9, a rear isometric view 900 of a trolley for servicing a server cassette in accordance with illustrative embodiments of the invention is shown. The trolley 800 includes one or more trolley handles 908 to allow maintenance personnel to move the trolley 800 within the data center, including between a rack 104 mounting server cassettes 108 and a server cassette 108 maintenance area. Various numbers and forms of handles 908 may be used on the trolley 800, including s single looped handle 908 as shown in FIG. 9.

In one embodiment, the trolley 800 may include a control panel 904. The control panel 904 is preferably mounted at a comfortable height for standing maintenance personnel to access, such as affixed to the trolley elevator 808. The control panel 904 may include controls and indicators associated with controlling the trolley platform 828, such as raising or lowering the trolley platform 828. In one embodiment, the controls may allow maintenance personnel to select a rack upper shelf 212 or lower shelf 216. In one embodiment, the controls may allow a rapid raising or lowering of the trolley platform 828, such as when no server cassette 108 is on the trolley rail 812. In another embodiment, the controls may allow a slow raising or lowering of the trolley platform 828, such as when a server cassette 108 is on the trolley rail 812 or when adjusting a relative height between the rack rail 404 and the trolley rail 812.

In one embodiment, the trolley control panel 904 may include a display. In one embodiment, the display may include annunciators for a current battery level of a trolley battery in the trolley power supply and actuator 820 or malfunction indicators associated with the actuator 820, the trolley elevator 808, or the trolley platform 828. In another embodiment, the display may include an alphanumeric display and one or more menus for display options. For example, one menu option may be to display a current battery charge level. Another menu option may be to display an operating or malfunction status of the actuator 820, elevator 808, or platform 828. Another menu option may display a current weight (lbs or kg) of a server cassette 108 on the trolley rail 812. The moving member within the trolley elevator 808 may have a weight sensor coupled to it and the weight sensor may report a current weight to the display. Another menu option may enable wireless

communication between the trolley 800 and other locations, including a server cassette 108 maintenance area. The control panel 904 may include a processor, memory, and a communication interface to enable WiFi, Bluetooth, or other form of wireless communications.

Referring to FIG. 10, a front isometric view of a server rack with a trolley servicing a server cassette 1000 in accordance with illustrative embodiments of the invention is shown. Maintenance personnel 1004 is shown in FIG. 10 servicing a server cassette 108 in a rack 104. The maintenance personnel 1004 is shown to provide a reference for the size of a common server cassette 108. FIG. 10 illustrates a server cassette 108 on the trolley platform 828. The server cassette 108 may have just been removed from the rack 104 or is prepared to be installed to an empty server cassette location of the rack 104. Although FIG. 10 illustrates the trolley platform 828 and the server cassette 108 at an upper shelf 212 height, in practice, the trolley 800 would not be moved within the data center while the trolley platform 828 carries a server cassette 108 in an elevated position for safety reasons. The center of mass of the server cassette 108/trolley 800 combination is higher when the server cassette 108 is being carried in an elevated position. A higher center of mass has a higher danger of tip-over than a lower center of mass.

Referring to FIG. 11, a detail view of a rack interface to a trolley rail 1100 in accordance with illustrative embodiments of the invention is shown. FIG. 11 illustrates the function of the rail alignment spacer 824 in aligning the rack rail 404 with the trolley rail 812. The rail alignment spacer 824 has a pair of lateral prongs that engage side surfaces of the rack rail 404 and ensure proper horizontal alignment for server cassette 108 transfer operations. As long as the maintenance personnel 1004 adjust the trolley rail 812 to have a same height as the rack rail 104, the rail alignment spacer 824 assures the two rails 404, 812 will be in axial alignment. When the rails 404, 812 are in axial alignment, the server cassette 108 may be smoothly and safely transferred between the rack 104 and the trolley 800.

FIG. 11 also illustrates fasteners 1104 that secure the server cassettes 108 to the rack rails 404. The rack rails 404 (and optionally the trolley rail 812 as well) may have a number

of vertical holes through which the fasteners 1104 engage the rails 404, 812. In one embodiment, the vertical holes may the threaded and match a thread pitch of the fasteners 1104. Fasteners 1104 may also be used to secure a server cassette 108 to the trolley rail 812.

Referring to FIG. 12, a flowchart of a server cassette removal process from a rack in a data center 1200 in accordance with illustrative embodiments of the invention is shown. Flow begins at block 1204.

At block 1204, maintenance personnel 1004 has determined that a server cassette 108 is to be removed from a rack 104 for some reason. The reason may include a failure of a server or various cooling components associated with a server cassette 108, a hardware upgrade of the server or cooling components, or a relocation of a server cassette 108. Flow proceeds to block 1208.

At block 1208, maintenance personnel 1004 requests that a server associated with a server cassette 108 to be serviced is taken offline. In one embodiment, a management computer may notify a server to go offline. In one embodiment, the server gracefully idles from program execution. In another embodiment, the server powers down after gracefully idling from program execution. Flow proceeds to block 1212.

At block 1212, maintenance personnel 1004 positions the trolley 800 in front of a server cassette 108 to be removed. The server cassette 108 is within a rack 104 of a data center. Flow proceeds to block 1216.

At block 1216, maintenance personnel 1004 move the trolley platform 828 to a desired approximate shelf height 212, 216. The shelf height 212, 216 corresponds to the shelf that holds the server cassette 108 to be removed. Flow proceeds to block 1220.

At block 1220, maintenance personnel 1004 removes fasteners 1104 and external fittings of the server cassette 108 to be removed from the rack 104. The fasteners 1104 may include one or more fasteners 1104 that secure the server cassette 108 to a specific position along a rack rail 404. The external fittings 620 may include connections to a secondary cooling loop of the data center, power connections to the server cassette 108, and any number of sensor cables attached to the server cassette 108. Flow proceeds to block 1224.

At block 1224, maintenance personnel 1004 adjust an elevator speed control 904 of the trolley 800 to match the trolley platform 828 rail height to the rack rail 404 height for the server cassette 108 to be removed. Flow proceeds to block 1228.

At block 1228, maintenance personnel 1004 push the trolley 800 toward the rack 104 to engage the rack rail 404 with the rail alignment spacer 824 of the trolley 800. The trolley 800 is pushed until the rail alignment spacer 824 is fully engaged to the rack rail 414. Flow proceeds to block 1232.

At block 1232, maintenance personnel 1004 locks the trolley wheels 804. In one embodiment, only the rear wheels have wheel locks. When the wheels are locked, the trolley 800 may not be moved. Flow proceeds to block 1236.

At block 1236, maintenance personnel 1004 pulls the server cassette 108 forward onto the trolley platform 828. The trolley platform 828 has a trolley rail 812 that exactly matches and is aligned with the rack rail 404. Once the server cassette 108 is fully pulled onto the trolley platform 828, in one embodiment the server cassette 108 may be secured to the trolley platform 828 with fasteners 1104 or other means. Flow proceeds to block 1240.

At block 1240, maintenance personnel 1004 unlocks the trolley wheels 804 and moves the trolley 800 backwards. This disengages the rail alignment spacer 824 from the rack rail 404. Flow proceeds to block 1244.

At block 1244, maintenance personnel 1004 lowers the trolley platform 828 supporting the server cassette 108 to a lowest level. In one embodiment, the lowest level may be a height of a lowest shelf 216 of the rack 104. In another embodiment, the lowest level may be lower than the height of the lowest shelf 216 of the rack 104. Flow proceeds to block 1248.

At block 1248, the maintenance personnel 1004 moves the trolley 800 holding the server cassette 108 to a service area and services the server cassette 108, as needed. Flow ends at block 1248.

Referring to FIG. 13, a flowchart of a server cassette installation process to a rack in a data center 1300 in accordance with illustrative embodiments of the invention is shown. Flow begins at block 1304.

At block 1304, maintenance personnel 1004 positions the trolley 800 in front of a rack 104 having an empty server cassette 108 location. The trolley platform 828 retains a server cassette 108 to install to the empty server cassette 108 location. Flow proceeds to block 1308.

At block 1308, maintenance personnel 1004 raise the trolley platform 828 to a desired approximate shelf height 212, 216. The shelf height 212, 216 corresponds to the shelf having the empty server cassette 108 location. Flow proceeds to block 1312.

At block 1312, maintenance personnel 1004 adjust an elevator speed control 904 of the trolley 800 to match the trolley platform 828 rail height to the rack rail 404 height for the empty server cassette 108 location. Flow proceeds to block 1316.

At block 1316, maintenance personnel 1004 push the trolley 800 toward the rack 104 to engage the rack rail 404 with the rail alignment spacer 824 of the trolley 800. The trolley 800 is then pushed until the rail alignment spacer 824 is fully engaged to the rack rail 404. Flow proceeds to block 1320.

At block 1320, maintenance personnel 1004 lock the trolley wheels 804. In one embodiment, only the rear wheels have wheel locks. When the wheels are locked 804, the trolley 800 may not be moved. Flow proceeds to block 1324.

At block 1324, maintenance personnel 1004 push the server cassette 108 backward onto the rack rail 404. The trolley platform 828 has a trolley rail 812 that exactly matches and is aligned with the rack rail 404. Once the server cassette 108 is fully pushed onto the rack rail 104, in one embodiment the server cassette 108 may be secured to the rack rail 404 with fasteners 1104 or other means. Flow proceeds to block 1328.

At block 1328, maintenance personnel 1004 unlocks the trolley wheels 804 and moves the trolley 800 backwards. This disengages the rail alignment spacer 824 from the rack rail 404. Flow proceeds to block 1332.

At block 1332, maintenance personnel 1004 attaches fasteners 1104 and external fittings of the server cassette 108 installed to the rack 104. The fasteners 1104 may include one or more fasteners 1104 that secure the server cassette 108 to a specific position along a rack rail 404. The external fittings may include connections to a secondary cooling loop 620 of the data center, power connections to the server cassette 108, and any number of sensor cables attached to the server cassette 108. Flow proceeds to block 1336.

At block 1336, maintenance personnel 1004 requests that the server associated with the installed server cassette 108 is brought online. In one embodiment, a management computer may notify a server to boot up and become online. Flow ends at block 1336.

Various embodiments of the invention have been described in fulfillment of the various objectives of the invention. It should be recognized that these embodiments are merely illustrative of the principles of the present invention. Numerous modifications and adaptions thereof will be readily apparent to those skilled in the art without departing from the spirit and scope of the present invention as defined in the following claims.

What is claimed is:

1. A server rack servicing system, comprising:
a rack, comprising:
a plurality of horizontal shelves, each shelf configured to store a plurality of vertically-disposed server cassettes; and
a movable trolley, comprising:
an elevator;
a platform, coupled to the elevator, configured to hold server cassettes removed from the rack or to be installed to the rack; and
an actuator, coupled to the elevator, configured to cause the elevator to move the platform to vertical shelf positions of the rack.

2. The server rack servicing system of claim 1, further comprising:
left and right fences, coupled to the platform and extending upward, configured to retain a server cassette on the platform and prevent the server cassette from falling sideways off the platform.

3. The server rack servicing system of claim 1, further comprising:
a plurality of pans, each below one of the plurality of shelves, configured to catch dielectric coolant leaks from the plurality of server cassettes, wherein each of the plurality of pans may be slidingly removed from the rack and emptied.

4. The server rack servicing system of claim 1, wherein the server cassettes each include a server, a primary loop cooling system, and a heat exchanger, wherein the primary loop cooling system circulates a dielectric coolant through a sprayer to cool the server and transfers heat to a secondary loop cooling system through the heat exchanger.

5. The server rack servicing system of claim 1, further comprising:
a plurality of rack rails, disposed below each of the plurality of server cassettes, configured to allow the server cassettes to slide in a forward or backward direction while preventing lateral movement of the server cassettes, wherein each of the plurality of server cassettes include a rail interface affixed to a bottom of the server cassette and configured to retain the server cassette to a rack rail.

6. The server rack servicing system of claim 5, wherein each rack rail comprises a plurality of vertical holes configured to secure a server cassette at different positions along the rack rail by a fastener.

7. The server rack servicing system of claim 6, wherein the platform includes a trolley rail affixed to a top surface of the platform, the trolley rail configured to allow the rail interface of server cassettes to slide in forward and backward directions along the trolley rail.

8. The server rack servicing system of claim 7, further comprising:
a rail alignment spacer, extending from a distal end of the platform, configured to engage an end of a rack rail to axially align the rack rail with the trolley rail when the trolley is moved forward to a server cassette position and the trolley rail is at a same height as a rack rail corresponding to the server cassette position.

9. The server rack servicing system of claim 8, further comprising:
wheel locks, coupled to a plurality of wheels of the trolley, configured to prevent trolley movement when the rail alignment spacer is coupled to the rack rail and the wheel locks are engaged.

10. The server rack servicing system of claim 8, wherein a server cassette may be pulled forwardly onto the platform in response to the fastener does not secure the server cassette to the rack rail and water and electrical connections at the rear of the server cassette have been disconnected.

11. The server rack servicing system of claim 8, wherein a server cassette may be pushed rearwardly from the platform onto the rack rail and secured to the rack rail with the fastener.

12. A method of removing a server cassette from a rack, comprising:
positioning a trolley in front of a server cassette to be removed from a rack, the rack comprising a plurality of horizontal shelves, each shelf configured to store a plurality of vertically-disposed server cassettes, the trolley comprising an elevator, a platform, coupled to the elevator, configured to hold server cassettes removed from the rack or to be installed to the rack, and an actuator, coupled to the elevator, configured to cause the elevator to move the platform to vertical shelf positions of the rack;
moving the platform to a shelf height of the rack corresponding to the server cassette to be removed;
engaging a rack rail of the server cassette to be removed with a rack alignment spacer coupled to a distal end of the platform such that the rack rail is axially aligned with a trolley rail coupled to the platform;
pulling the server cassette forward onto the trolley rail;
moving the trolley in a backward direction from the rack to disengage the rack alignment spacer from the rack rail; and
lowering the platform, by the actuator, to a vertical height on the trolley deemed as safe for transporting the server cassette on the trolley.

13. The method of claim 12, wherein before pulling the server cassette forward, the method further comprises:
uncoupling the server cassette to be removed from the rack rail, by removing a fastener; and
disconnecting cooling and electrical connections to the server cassette.

14. The method of claim 13, wherein before disconnecting cooling and electrical connections to the server cassette, the method further comprises:
inactivating a server in the server cassette.

15. The method of claim 12, wherein before engaging the rack rail of the server cassette to be removed with the rack alignment spacer, the method further comprises:
adjusting, by an elevator speed control of the trolley, a height of the platform until the rack rail is axially aligned with the trolley rail.

16. The method of claim 12, wherein before pulling the server cassette forward onto the trolley rail, the method comprises:
locking, by wheel locks affixed to a plurality of trolley wheels, the plurality of trolley wheels to prevent trolley movement.

17. A method of installing a server cassette to a rack, comprising:
positioning a trolley in front of an empty server cassette position in a rack, the rack comprising a plurality of horizontal shelves, each shelf configured to store a plurality of vertically-disposed server cassettes, the trolley comprising an elevator, a platform, coupled to the elevator, supporting a server cassette to be installed to the rack, and an actuator, coupled to the elevator, configured to cause the elevator to move the platform to vertical shelf positions of the rack;
moving the platform to a shelf height of the rack corresponding to the empty server cassette position;
engaging a rack rail corresponding to the empty server cassette position with a rack alignment spacer coupled to a distal end of the platform such that the rack rail is axially aligned with a trolley rail coupled to the platform and supporting the server cassette to be installed;
pushing the server cassette backward into the empty server cassette position along the rack rail; and
moving the trolley in a backward direction from the rack to disengage the rack alignment spacer from the rack rail.

18. The method of claim 17, wherein before engaging the rack rail of the server cassette to be installed with the rack alignment spacer, the method further comprises:
adjusting, by an elevator speed control of the trolley, a height of the platform until the rack rail is axially aligned with the trolley rail.

19. The method of claim 17, wherein before pushing the server cassette backward onto the rack rail, the method comprises:
locking, by wheel locks affixed to a plurality of trolley wheels, the plurality of trolley wheels to prevent trolley movement,
wherein after pushing the server cassette backward onto the rack rail, the method comprises:
unlocking the wheel locks.

20. The method of claim 17, wherein after pushing the server cassette backward onto the rack rail, the method further comprises:
securing the server cassette to the rack rail, by a fastener; and
connecting cooling and electrical connections to the server cassette.
